(19) United States
(12) Patent Application Publication
(10) Pub. No.: US 2008/0170229 A1
(43) Pub. Date: Jul. 17, 2008

(54) METHOD OF SELECTING CRYSTALLINE QUARTZ MATERIAL FOR USE IN AN OPTICAL APPARATUS

(75) Inventor: Wilfried Clauss, Tuebingen (DE)

Correspondence Address: FISH & RICHARDSON PC, P.O. BOX 1022, MINNEAPOLIS, MN, 55440-1022, US

(73) Assignee: CARL ZEISS SMT AG, Oberkochen (DE)

(21) Appl. No.: 11/968,981

(22) Filed: Jan. 3, 2008

Related U.S. Application Data
(60) Provisional application No. 60/880,608, filed on Jan. 16, 2007.

(51) Int. Cl. G01N 21/55; G03F 1/00

(52) U.S. Cl. 356/433; 430/4

(57) ABSTRACT

Methods of selecting crystalline quartz material for use in an optical apparatuses are disclosed. In some embodiments, the methods can enable a relatively fast, simple and/or reliable selection of samples with respect to their lifetime properties under laser irradiation.

### CROSS-REFERENCE TO RELATED APPLICATION

This application claims priority under 35 U.S.C. §119(e)(1) to U.S. Ser. No. 60/880,608, filed Jan. 16, 2007, which is hereby incorporated by reference.

### FIELD

The disclosure relates to methods of selecting crystalline quartz materials for use in an optical apparatuses, such as microlithographic exposure apparatuses.

### BACKGROUND

Crystalline quartz represents a desirable raw material for the use in a microlithographic exposure apparatus because of its mechanical and optical properties. These properties include e.g. the deterministic birefringence which occurs in crystalline quartz and which may be, depending on the orientation of the optical crystal axis in the crystalline quartz material with respect to the light propagation direction or the direction of the optical system axis, linear birefringence if the crystal axis is orientated perpendicular to light propagation direction, or circular birefringence, also referred to as “optical activity”, if the crystal axis is orientated parallel to light propagation direction. By way of an example, the latter property of crystalline quartz to exhibit circular birefringence qualifies quartz as being a principally suitable material in polarization-modulating optical elements.

### SUMMARY

The disclosure relates to methods of selecting crystalline quartz materials for use in an optical apparatuses, such as microlithographic exposure apparatuses.

In some embodiments, the disclosure provides methods of selecting crystalline quartz material for use in an optical apparatuses. This can enable a relatively fast, simple and/or reliable selection of samples with respect to their lifetime properties under laser irradiation. In certain embodiments, the method enables a relatively fast, simple and/or reliable selection of samples that are suitable, with respect to lifetime under laser irradiation, for use in a microlithographic processes.

In one aspect, the disclosure provides a method that includes measuring a first transmittance spectrum of a sample of a crystalline quartz material in a predefined wavelength regime, and irradiating the sample with laser pulses having an energy density of at least 50 mJ/cm². The method also includes, after irradiating the sample, measuring a second transmittance spectrum in the predefined wavelength regime. In addition, the method includes evaluating the suitability of the crystalline quartz material for use in an optical apparatus based upon the first and the second transmittance spectrum.

A method for manufacturing an optical system of a microlithographic exposure apparatus, in particular for manufacturing an illumination system, wherein the optical system includes at least one optical element including a crystalline quartz material which has been selected using the method according to anyone of the preceding claims.

In another aspect, the disclosure provides a method that includes delivering crystalline quartz material to a customer, wherein the quartz material is selected by a method as described in the preceding paragraph.

In another aspect, the disclosure features a method that includes selecting a crystalline quartz material by the method provided in two paragraphs above, and ordering the crystalline quartz material from a manufacturer.

In a further aspect, the disclosure features a method that includes ordering quartz from a manufacturer, wherein the ordering includes specifying that the quartz has an absorption parameter value that is no more than a threshold value, the absorption parameter being related to a variation in the absorption of the quartz before and after irradiation of the quartz with laser radiation.

In an additional aspect, the disclosure features a method that includes receiving an order for quartz, wherein the ordering includes specifying that the quartz has an absorption parameter value that is no more than a threshold value, the absorption parameter being related to a variation in the absorption of the quartz before and after irradiation of the quartz with laser radiation.

In another aspect, the disclosure provides a method that includes selecting quartz material based on a value of an absorption parameter of the quartz, and delivering the quartz material to a customer, wherein the absorption parameter is related to a variation in the absorption of the quartz before and after irradiation of the quartz with laser radiation.

Embodiments can include one or more of the following features.

In some embodiments, evaluating the suitability includes determining an absorption parameter value based upon the first and the second transmittance spectrum, the absorption parameter being related to a variation in the absorption of the sample before and after irradiation, and comparing a maximum value of the absorption parameter value with a predefined threshold value. In certain embodiments, the absorption parameter value is related to a maximum difference in transmission between the irradiated sample and the non-irradiated sample in the predefined wavelength regime. In some embodiments, the absorption parameter is related to an integral of the difference of the transmissions, or to an integral of the ratio of the transmissions, of the irradiated sample and of the non-irradiated sample in the predefined wavelength regime.

In some embodiments, irradiating the sample includes using laser pulses having an energy density H of at least 60 mJ/cm², e.g., at least 70 mJ/cm². In certain embodiments, irradiating the sample includes using laser pulses having a total number N not exceeding a value of 2*10⁵, e.g., not exceeding a value of 5*10⁴, not exceeding a value of 3*10⁴, not exceeding a value of 2*10⁴. In some embodiments, irradiating the sample includes using laser pulses having a pulse duration not exceeding 30 ns, e.g., not exceeding 25 ns. In certain embodiments, the irradiating the sample includes using an ArF-laser

In certain embodiments, the predefined wavelength regime ranges from 250 nm to 800 nm, such as from 350 nm to 500 nm.

In some embodiments, the method further includes determining, over a predetermined spatial regime of the sample, a maximum misalignment of the optical crystal axis with respect to a predefined orientation of the optical crystal axis, wherein evaluating the suitability of the crystalline quartz material is also based upon the so determined maximum misalignment. In certain embodiments, evaluating the crystalline quartz material as suitable only if the maximum misalignment of the optical crystal axis is less than 0.1°, e.g., less than 0.05°.

In some embodiments, the method further includes determining, over a predetermined spatial regime of the sample, a maximum variation of the refractive index of the crystalline quartz material, wherein evaluating the suitability of the crystalline quartz material is also based upon the so determined maximum variation of the refractive index. In certain embodiments, the crystalline quartz material is evaluated as being suitable only if the maximum variation of the refractive index of the crystalline quartz material is less than 5 ppm.

In certain embodiments, the optical apparatus is a microlithographic exposure apparatus, e.g., an illumination system of a microlithographic exposure apparatus.

In some embodiments, the threshold value corresponds to a variation of about 5% or less, e.g., about 2%.

It has been empirically observed that the laser-induced absorption may, at least in good approximation, be described by a fixed relation to the associated operating conditions, namely the energy density H, the pulse number N and the pulse duration τ, under which the laser-induced absorption is created. This fixed relation is given, for crystalline quartz and an operating wavelength of λ≈193 nm, in relation (1):

Δk∞N*H/τ^{0,4} (1)

In relation (1), Δk denotes the laser-induced absorption, i.e. the difference between the absorption coefficients k before and after laser irradiation, with the absorption coefficient k being defined in relation (2)

k=−log₁₀(T/d) (2)

wherein d denotes the thickness of the sample and wherein T denotes the transmittance being related with the absorption defined by equation (3)

T=1−A (3)

The disclosure is further based on the consideration that, due to the above fixed relation (1), it becomes possible to significantly modify the testing conditions for testing a sample, i.e. examining its “lifetime” considering deteriorations of the transmittance with increasing time of operation, in comparison to the real operating parameters to which the sample is subjected in a microlithographic exposure process. The disclosure particularly considers the fact that a realization of these real operating parameters of the microlithographic exposure process, which typically correspond to energy densities of the exposure light of H≈(2-5) mJ/cm², typical numbers of pulses N of 10¹¹ pulses during a typical period of warranty of the illumination system of e.g. 5 years, and typical pulse durations of τ≈150 ns, would result in a time consuming and costly testing method.

In some embodiments, an effective testing method is provided which, according to a suitable modification of the testing parameters, considerably reduces the required time and costs and which still yields a reliable result and statement regarding the suitability of the tested sample for microlithographic applications.

It has been found that an irradiation as performed in a typical inventive testing method, namely with a relatively large energy density of H≈50-70 mJ/cm², a relatively low number of pulses of N≈20.000-180.000 and relatively low pulse durations of τ≈25 ns, results in characteristic, broad absorption bands appearing in the wavelength dependency of the transmission (or the so-called spectral absorption, respectively) the size of which represents a reliably criterion on the rating of the tested sample in terms of the above lifetime problem.

Evaluating the suitability of the crystalline quartz material based upon the first and the second transmittance spectrum may, in particular, include evaluating the suitability of the crystalline quartz material based upon a comparison between the first and the second transmittance spectrum.

In certain embodiments, evaluating the suitability of the crystalline quartz material includes:
determining an absorption parameter value based upon the first and the second transmittance spectrum, the absorption parameter being related to a variation in the absorption of the quartz before and after irradiation; and
comparing the so determined maximum value with a predefined threshold value.

In some embodiments, the absorption parameter is related to a maximum difference in transmission between the irradiated sample and the non-irradiated sample in the predefined wavelength regime.

In certain embodiments, the absorption parameter is related to an integral of the difference of the transmissions, or to an integral of the ratio of the transmissions, of the irradiated sample and of the non-irradiated sample in the predefined wavelength regime.

In some embodiments, irradiating the sample is performed using laser pulses having a pulse duration not exceeding 30 nm, e.g., not exceeding 25 ns. This can be advantageous since it has been found in consistence with the above relation (1) that for such relatively low pulse durations an irradiation-induced “damage” or deterioration of transmittance is achieved on a shorter time scale if compared to larger pulse durations, e.g. typical pulse durations of τ≈(100-150) ns used in the microlithographic process. Consequently, the necessary time effort for the inventive selection is further reduced.

In some embodiments, the crystalline quartz material being tested is regarded as suitable for use in an illumination system of a microlithographic exposure apparatus only if a maximum misalignment of the optical crystal axis with respect to a predefined orientation is less than 0.1°, e.g., less than 0.05°, over a predetermined spatial regime of the sample, which may be tested in a suitable adapted X-ray diffractometer.

In certain embodiments, the crystalline quartz material being tested is regarded as suitable for use in an illumination system of a microlithographic exposure apparatus only if a maximum variation of the refractive index of the crystalline quartz material is less than 5 ppm over a pre-determined spatial regime of the sample.

The consideration of these further criterions is advantageous in so far as it guarantees that the desired optical effect, which usually is substantially based upon the birefringent properties of the material, is at least substantially constant over the optically used region of the material.

The disclosure also relates to a method for manufacturing an optical system of a microlithographic exposure apparatus, in particular for manufacturing an illumination system, wherein the optical system includes at least one optical element including a crystalline quartz material which has been selected using a method as described above. Furthermore, the disclosure also relates to a method of ordering crystalline quartz material from a manufacturer, the method including the step of instructing the manufacturer to deliver only crystalline quartz material which has been selected by a selecting method as described above.

### BRIEF DESCRIPTION OF THE DRAWINGS

The disclosure is described in more detail with reference to the following detailed description, in which:

FIG. 1 shows a flowchart used to explain the testing method of the present invention according to a preferred embodiment;

FIG. 2 shows a measured wavelength-dependency of the optical transmittance, which is measured during a testing method for a sample before laser-irradiation (broken line) and after laser-irradiation (solid line) with 20.000 laser-pulses having an energy density of H=70 mJ/cm²;

FIG. 3 shows the correlation between the irradiation-induced absorption if determined with one method (“rapid test”, vertical axis) and the irradiation-induced absorption if determined under real operation conditions in an illumination system (“long-term test, horizontal axis); and

FIG. 4 is a diagram showing the dependency of irradiation-induced absorption of the number of laser-pulses for two different pulse durations.

### DETAILED DESCRIPTION

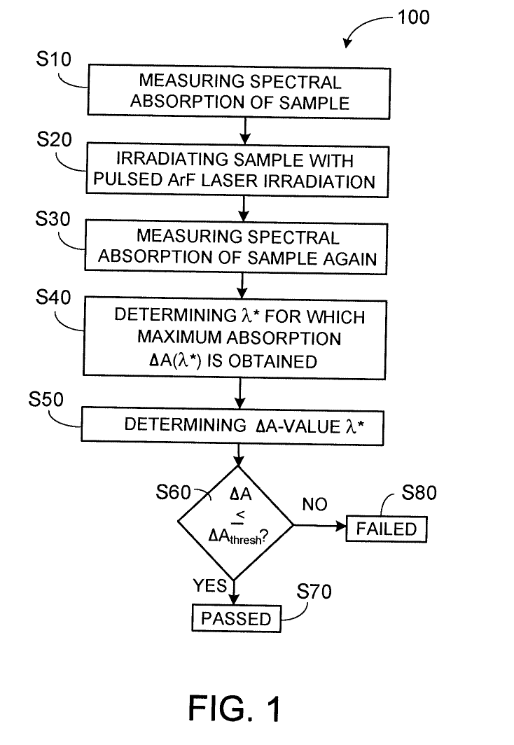

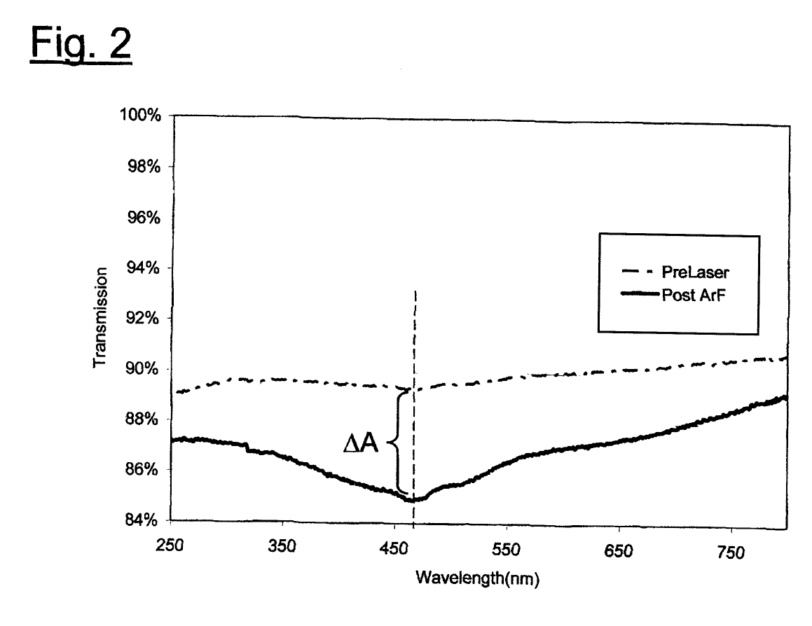

In the following, a testing method according to the pre-sent disclosure is described by way of an exemplary embodiment with reference the flowchart 100 given in FIG. 1. In order to perform the inventive “rating” of a specific sample of crystalline quartz material, as a first step S10 the wavelength-dependency of the transmittance (also referred to as the “spectral absorption”) is measured for this sample, e.g., in a wavelength-region from 250 nm to 800 nm. The so-obtained transmittance spectrum is represented by the dashed line in FIG. 2.

In a next step S20, the same sample is irradiated with pulsed laser-irradiation from an Argon-Fluoride laser (ArF-laser). This irradiation is generally performed with a relatively large energy density, a relatively low number of pulses and relatively low pulse durations. Here and in the following, the terms “relatively large” and “relatively low” are to be understood in comparison to the real operation conditions in the illumination system of a microlithographic exposure apparatus. Typical operation conditions in the illumination system correspond to energy densities of H≈(2-5)mJ/cm², a number of pulses of 10¹¹ pulses during a typical period of warranty of the illumination system of, e.g., 5 years, and pulse durations of τ≈150 ns. In comparison thereto, the afore mentioned parameters selected in the inventive testing method are: H (energy density)=50-70 mJ/cm², N (number of pulses)=20.000-180.000 and τ (pulse duration)=25 ns.

After the afore described irradiation of step S20, the transmittance spectrum in the wavelength region from 250 to 800 nm is measured again in step S30, resulting in the second curve illustrated with the solid line in FIG. 2.

As can be gathered from FIG. 2, the observed irradiation-induced absorption (corresponding to the difference between the transmittance values before and after irradiation) takes a maximum value at a wavelength λ* of ≈470 nm. This value of the wavelength is determined in step S40. The respective value of the laser induced absorption obtained at this wavelength is designated, here and in the following, as ΔA, and is determined in the following step S50.

As an alternative method for determining the strength of the induced absorption, the size of the area enclosed by both spectra, before and after irradiation, can be numerically determined by computing the integral value:

$$I = {\int }_{{λ}_{1}}^{{λ}_{2}} ( {T}_{nonirradiated} - {T}_{irradiated} ) d λ \qquad ( 4 )$$

Here, λ₁ and λ₂ denote the lower and upper boundary for evaluating the integral. T_{nonirradiated}(λ) and T_{irradiated}(λ) are the transmission spectra before and after irradiation.

It is to be noted that any other numerical method can be used which is able to determine quantitatively the impact resulting from the irradiation onto the transmission curve of the tested material.

In the next step S60, it is asked whether the value of ΔA which has been determined in step S50 is not exceeding a certain limit or threshold ΔA_{threshold}. The inventive selection is now performed in such a way that the tested sample is either rated in step S70 as “passed” if the value of ΔA is equal to or below the threshold ΔA_{threshold}, whereas this sample is rated in step S80 as “failed”, if the value of ΔA is beyond the threshold ΔA_{threshold}.

A suitable threshold value ΔA_{threshold} giving a sufficient stability of the transmission properties under irradiation in the illumination system has been determined to ΔA_{threshold}≈2%. If another method for data evaluation, for example the integral method, is chosen, the threshold value for this method has to be adjusted accordingly.

The above criterion is based on the consideration that a typical specification of an illumination system requests that the loss in transmittance with increasing total operation time should not exceed a relative amount of 10%, which means that for an initial transmittance of T₁=80%, the decrease of transmittance with increasing total operation time should not lead to a transmittance value of T₂=(80−0.1*80)%=72%. Furthermore, the total operation time should typically reach a period of at least 5 years, typically corresponding to a number of pulses of 5 Gigashots (i.e. N=5*10⁹).

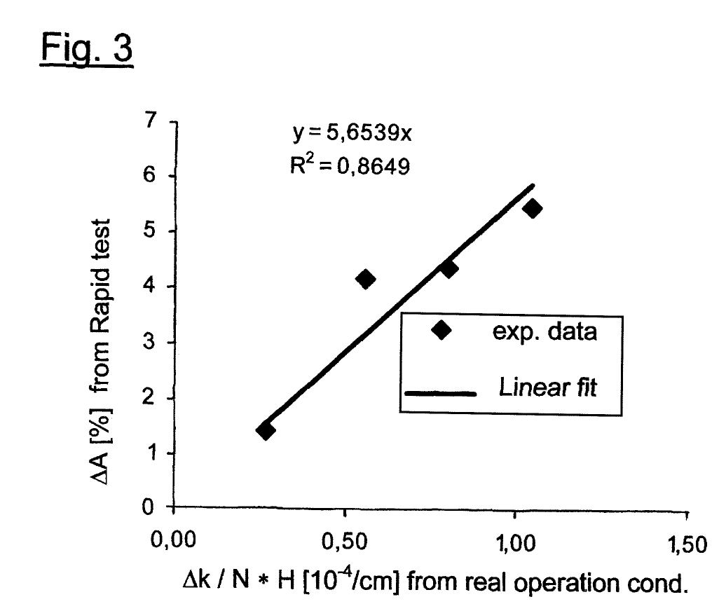

FIG. 3 shows for a total of four samples, the obtained ΔA-values at the vertical axis in the diagram. The attributed values at the horizontal axis in this diagram denote a measured difference in the absorption coefficient for irradiation under real operation conditions (corresponding to a relatively lower energy density of typically 2 to 5 mJ/cm², relatively large pulse numbers of several 10⁹ pulses or “Giga-shots” and relatively large pulse durations of typically 150 ns). Furthermore, the irradiation-induced absorption obtained for real operation conditions is plotted along the horizontal axis in FIG. 3 after division by (i.e. normalization to) the deposited energy, i.e. division by the product N*H (=number of pulses, in Gigashots multiplied with energy density).

As can be gathered from FIG. 3, the correlation between the value ΔA being determined in the inventive test according to the flowchart 100 of FIG. 1 and the value Δk/N*H corresponding to real operation conditions approximately shows a linear dependency with a regression factor R²=0.8649, which demonstrates the expressiveness and validity of the testing method of the present disclosure. The definition of a suitable limit or criterion for the suitability of the respective tested crystal quartz material corresponds to the specification of a vertical borderline in FIG. 3, which again corresponds to a horizontal threshold value of ΔA.

Based on the above explained correlation between the value ΔA being determined in the inventive test (y-axis in FIG. 3) and the value Δk/N*H corresponding to real operation conditions to be expected during the microlithographic process, it also becomes possible to conclude from a measured value for ΔA to a corresponding value Δk/N*H, and consequently to deduce the laser-induced absorption coefficient to be expected for realistic values of the pulse number N and the energy density H.

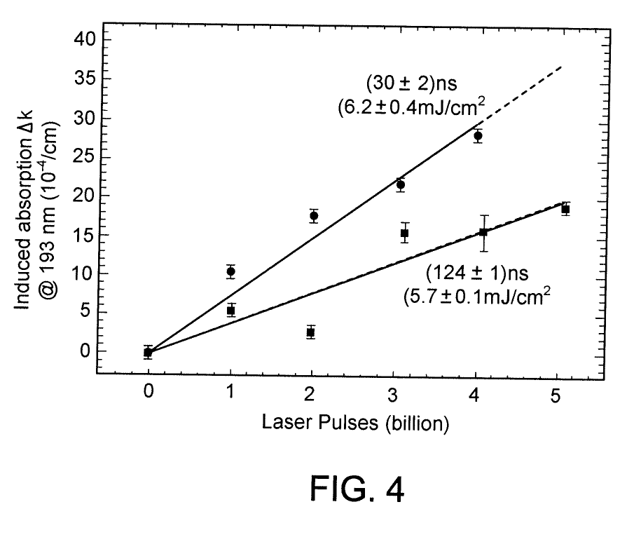

FIG. 4 shows the dependency of irradiation-induced absorption on the number of laser-pulses for two different pulse durations of τ₁≈30 ns and τ₂≈124 ns and with similar energy densities (of H₁≈6.2 mJ/cm² and H₁≈5.7 mJ/cm²), the energy densities corresponding to typical operating conditions in the microlithographic process. The diagram of FIG. 4 shows the result of a typical long-term measurement (comparable to values plotted on the x-axis in the diagram of FIG. 3), wherein the measurement points have been determined by measuring the irradiation-induced absorption after 1 Giga-shot of pulses, irradiating the sample with a further Giga-shot of pulses, again measuring the irradiation-induced absorption etc. It can be seen from the diagram that for both pulse durations of T₁≈30 ns and τ₂≈124 ns, the irradiation-induced absorption shows an approximately linear dependence on the number of pulses, wherein the lower slope of the linear approximation is obtained for the longer pulse duration τ₂. This result is consistent with the above relation (1), which has been empirically obtained by evaluating a plurality of samples being irradiated with different pulse durations.

Although the disclosure has been described on the basis of a specific embodiment, a person skilled in the art will also infer numerous variations and alternative embodiments, e.g. by combining and/or exchanging features of individual embodiments. Accordingly, it will be readily understood by a person skilled in the art that these variations and alternative embodiments are also encompassed by the present disclosure, and the scope of the disclosure is restricted only by the appended claims and their equivalents.

What is claimed is:

1. A method, comprising:
measuring a first transmittance spectrum of a sample of a crystalline quartz material in a predefined wavelength regime;
irradiating the sample with laser pulses having an energy density of at least 50 mJ/cm²;
after irradiating the sample, measuring a second transmittance spectrum in the predefined wavelength regime; and
evaluating the suitability of the crystalline quartz material for use in an optical apparatus based upon the first and the second transmittance spectrum.

2. The method according to claim 1, wherein evaluating the suitability comprises:
determining an absorption parameter value based upon the first and the second transmittance spectrum, the absorption parameter being related to a variation in the absorption of the sample before and after irradiation; and
comparing a maximum value of the absorption parameter value with a predefined threshold value.

3. The method according to claim 2, wherein the absorption parameter value is related to a maximum difference in transmission between the irradiated sample and the non-irradiated sample in the predefined wavelength regime.

4. The method according to claim 2, wherein the absorption parameter is related to an integral of the difference of the transmissions, or to an integral of the ratio of the transmissions, of the irradiated sample and of the non-irradiated sample in the predefined wavelength regime.

5. The method according to claim 1, wherein irradiating the sample comprises using laser pulses having an energy density H of at least 60 mJ/cm².

6. The method according to claim 1, wherein irradiating the sample comprises using laser pulses having a total number N not exceeding a value of 2*10⁵.

7. The method according to claim 1, wherein irradiating the sample comprises using laser pulses having a pulse duration not exceeding 30 ns.

8. The method according to claim 1, wherein the predefined wavelength regime ranges from 250 nm to 800 nm.

9. The method according to claim 1, wherein the predefined wavelength regime ranges from 350 nm to 500 nm.

10. The method according to claim 1, wherein the irradiating the sample comprises using an ArF-laser.

11. The method according to claim 1, further comprising determining, over a predetermined spatial regime of the sample, a maximum misalignment of the optical crystal axis with respect to a predefined orientation of the optical crystal axis, wherein evaluating the suitability of the crystalline quartz material is also based upon the so determined maximum misalignment.

12. The method according to claim 11, wherein evaluating the crystalline quartz material as suitable only if the maximum misalignment of the optical crystal axis is less than 0.1°.

13. The method according to claim 1, further comprising determining, over a predetermined spatial regime of the sample, a maximum variation of the refractive index of the crystalline quartz material, wherein evaluating the suitability of the crystalline quartz material is also based upon the so determined maximum variation of the refractive index.

14. The method according to claim 13, wherein the crystalline quartz material is evaluated as being suitable only if the maximum variation of the refractive index of the crystalline quartz material is less than 5 ppm.

15. The method according to claim 1, wherein the optical apparatus is a microlithographic exposure apparatus.

16. A method for manufacturing an optical system of a microlithographic exposure apparatus, in particular for manufacturing an illumination system, wherein the optical system comprises at least one optical element comprising a crystalline quartz material which has been selected using the method according to anyone of the preceding claims.

17. A method, comprising:
delivering crystalline quartz material to a customer,
wherein the quartz material is selected by a method according to claim 1.

18. A method, comprising:
selecting a crystalline quartz material by a method according to claim 1; and
ordering the crystalline quartz material from a manufacturer.

19. A method, comprising:
ordering quartz from a manufacturer,
wherein the ordering comprises specifying that the quartz has an absorption parameter value that is no more than a threshold value, the absorption parameter being related to a variation in the absorption of the quartz before and after irradiation of the quartz with laser radiation.

20. A method, comprising:
receiving an order for quartz,
wherein the ordering comprises specifying that the quartz has an absorption parameter value that is no more than a threshold value, the absorption parameter being related to a variation in the absorption of the quartz before and after irradiation of the quartz with laser radiation.

21. A method, comprising:
selecting quartz material based on a value of an absorption parameter of the quartz; and
delivering the quartz material to a customer,
wherein the absorption parameter is related to a variation in the absorption of the quartz before and after irradiation of the quartz with laser radiation.

22. The method according to claim 19, wherein the absorption parameter is related to a maximum difference in transmission between the irradiated sample and the non-irradiated sample in a predefined wavelength regime.

23. The method according to claim 19, wherein the absorption parameter is related to an integral of the difference of the transmissions, or to an integral of the ratio of the transmissions, of the irradiated sample and of the non-irradiated sample in a predefined wavelength regime.

24. The method of claim 22, wherein the range of wavelengths is from about 250 nm to about 750 nm.

25. The method according to claim 19, wherein the laser radiation is ArF laser radiation.

26. The method of claim 19, wherein the threshold value corresponds to a variation of about 5% or less.

27. The method of claim 19, wherein the threshold value corresponds to a variation of about 2%.
